(19) United States
(12) Patent Application Publication
(10) Pub. No.: US 2002/0066904 A1
(43) Pub. Date: Jun. 6, 2002

(54) Solid-state relay having integrated organic light-emitting diodes

(76) Inventors: Han-Tzong Yuan, Dallas, TX (US); Tae S. Kim, Dallas, TX (US); Francis G. Celii, Dallas, TX (US); Simon J. Jacobs, Lucas, TX (US)

Correspondence Address: TEXAS INSTRUMENTS INCORPORATED, P O BOX 655474, M/S 3999, DALLAS, TX, 75265

(21) Appl. No.: 09/729,300

(22) Filed: Dec. 4, 2000

Related U.S. Application Data
(60) Provisional application No. 60/168,969, filed on Dec. 3, 1999.

(51) Int. Cl. H01L 27/15; H01L 31/153; H02P 5/28

(52) U.S. Cl. 257/83; 438/22; 438/24; 257/84

(57) ABSTRACT

A solid-state relay is created by a power-switching device embedded in a semiconductor wafer which includes an optically transparent, electrically insulating surface, an organic light-emitting diode (OLED) formed on that surface, and a light-absorbing device integrated with the power-switching device, electrically isolated from the diode, and positioned in the path of the emitted light.

### FIELD OF THE INVENTION

The present invention is related in general to the field of semiconductor devices and processes and more specifically to the use of organic light-emitting diodes for solid-state relays.

### DESCRIPTION OF THE RELATED ART

Commercial light emitting diodes (LEDs) typically constitute a p-n junction of inorganic, doped semiconducting materials such as gallium arsenide (GaAs) or aluminum gallium arsenide (AlGaAs). At these junctions between the doped layers, recombination of electrons and holes results in interband emission of light.

Heteroepitaxial growth of direct bandgap III-V compound semiconductors such as GaAs, InP, and GaP on silicon substrates, from which LEDs can be fabricated, yields highly defective material due to mismatches in lattice parameters and thermal expansion coefficients. These LEDs do not perform well, and the silicon devices are affected during the heteroepitaxy due to the required high growth temperatures (typically>600° C.). Achieving good electrical isolation is also not easy in these approaches, making the fabrication of solid-state relays problematic.

As an alternative, III-V LEDs have been integrated with a silicon drive circuits and power switching device at the package level; for instance, see U.S. Pat. No. 5,159,700, issued Oct. 27, 1992 (Reid, deceased et al., “Substrate with Optical Communication Systems between Chips Mounted thereon and Monolithic Integration of Optical I/O on Silicon Substrates”), based on U.S. Pat. No. 5,009,476, issued Apr. 23, 1991 (Reid et al., “Semiconductor Layer with Optical Communication between Chips Disposed therein”). But these approaches are expensive and not suitable for wafer-level integration.

Recently, organic light-emitting diodes (OLEDs) have drawn much attention, especially for emissive display applications. Since OLEDs can be fabricated on any smooth surface, such as silicon wafers, and at low (<100° C.) temperatures, they are also very promising for many optoelectronic applications. Electroluminescent devices have been constructed using multi-layer organic films. Basic structure and working are described in “Electroluminescence of Doped Organic Thin Films” (J. Appl. Phys., vol. 65, pp. 3610-3616, 1989) by C. W. Tang, S. A. VanSlyke, and C. H. Chen. The review article “Status of and Prospects for Organic Electroluminescence” (J. Materials Res., vol. 11, pp. 3174-3187. December 1996, by L. J. Rothberg and A. J. Lovinger) describes various OLED device structures in the form of stacks of thin layers with carrier injection and transverse current flow. For example, the stack may be a transparent substrate (for instance, glass), a transparent anode (for instance, indium-tin oxide, ITO), a hole transport layer (for instance, TPD), an emissive layer which also is an electron transport layer and in which electron-hole recombination and luminescence occur (for instance, Alq3), and a cathode (a metal with low work function, for instance, magnesium or a magnesium-containing alloy such as Mg:Ag). “TPD” is N,N′-diphenyl-N,N′-bis (3-methylphenyl)-1,1′biphenyl-4,4′diamine. “Alq3” is tris(8-hydroxy) quinoline aluminum.

A different approach using siloxane self-assembly techniques, has been described in U.S. Pat. No. 5,834,100, issued on Nov. 10, 1998 (Marks et al., “Organic Light-Emitting Diodes and Method for Assembly and Emission Control”).

In addition to the OLEDs, many related devices such as organic laser diodes, photodetectors, etc. may be realized using organic semiconductors. For many applications such as on-chip interconnects, laser diodes are preferred over LEDs. Laser action has been demonstrated in polymeric organic films, but only by employing optical pumping (for instance, “Laser Emission from Solutions and Films Containing Semiconducting Polymer and Titanium Dioxide Nanocrystals”, Chem. Phys. Lett., vol. 256, pp. 424-430, 1996, by F. Hide, B. J. Schwartz, M. A. Diaz-Garcia, and A. J. Heeger; “Lasing from Conjugated-Polymer Microcavities”, Nature, vol. 382, pp. 695-697, by N. Tessler, G. J. Denton, and R. H. Friend; “Semiconducting Polymers: a New Class of Solid-State Laser Materials”, Science, vol. 273, pp. 1833-1836, 1996, by F. Hide, M. A. Diaz-Garcia, B. J. Schwartz, M. R. Andersson, Q. Pei, and A. J. Heeger). Inadequate charge injection is the main roadblock in achieving an organic-based solid-state laser from electrically pumped organic films. The optical linking of OLEDs with light-sensitive devices has been described in U.S. Pat. No. 5,907,160, issued May 25, 1999 (Wilson et al., “Tin Film Organic Light Emitting Diode with Edge Emitter Waveguide”).

In their paper “Enhanced Electron Injection in Organic Electroluminescence Devices using an Al/LiF Electrode” (Appl. Phys. Lett., vol. 70, pp.152-154, 1997), L. S. Hung, C. W. Tang, and M. G. Mason disclose the beneficial effects of inserting an inorganic dielectric layer (LiF, thin enough for electron tunneling, 0.5 to 1.0 nm) between the metal cathode (Al) and organic material. The energy bands of Alq3 are bent downwards by the contact with LiF, thus substantially lowering the electronic barrier height of the Alq3-Al interfaces and enhancing the electron injection. The operating voltage is reduced and cathode metals of higher work function can be used. Further, the devices employ a thin (15 nm) buffer layer at the anode (ITO), comprised of CuPc (copper phthalocyanine). The hole transport layer is NPB (N,N′-bis(1-naphthyl)-N,N′-diphenyl-1,1′-biphenyl-4,4′-diamine). Alq3 is the emissive as well as electron transport layer.

Methods for fabrication and characterization (such as film thickness, and light intensity and wavelength) have been described in “Characterization of Organic Thin Films for OLEDs using Spectroscopic Ellipsometry” (F. G. Celii, T. B. Harton, and O. F. Phillips, J. Electronic Materials, vol. 26, pp. 366-371, 1997). The organic materials may be amorphous or polycrystalline discrete molecular, or may be polymeric. Polymer layers differ from discrete molecular layers because they are typically not fabricated by vacuum vapor deposition, but rather by spin coating from an appropriate solvent. The polymeric layers may also be deposited (either by vapor deposition or by spin coating) as pre-polymer layers and then converted either thermally or photochemically to the active form. Spin coating, spin casting, or melt techniques have the advantage of large area coverage and low fabrication cost.

The state of the art has been advanced by three recent patent applications to which the present invention is related. In U.S. patent application Ser. No. 09/156,166, filed on Sep. 17, 1998 (Celii et al., “Organic Light Emitting Diodes”), an OLED is provided with dielectric barriers at both the anode-organic and cathode-organic interfaces. Increased carrier injection efficiencies and increased overall OLED efficiency plus lower voltage operation are thus enabled. The subsequent U.S. Patent Application No. 60/165,060, filed on Nov. 12, 1999 (Jacobs et al., “Structure and Method of Electrically-Pumped Organic Laser Diodes using Charge-Injection Layers”) applies the high injection efficiency to organic lasers. The further U.S. patent application (TI-26315, Kim et al., “Photolithographic Method for Fabricating Organic Light-Emitting Diodes”) introduces mass-production techniques, compatible with silicon technology, to OLED fabrication.

A challenge has therefore arisen to conceive structures and fabrication methods for solid-state relays having integrated organic light-emitting diodes suitable for miniaturization and high process yield. Preferably, this concept should be based on fundamental design solutions flexible enough to be applied for different diode, laser and integrated circuit product families and a wide spectrum of material and assembly variations. Manufacturing should be low cost and the devices stable and reliable. Preferably, the innovations should be accomplished using established fabrication techniques and the installed equipment base.

### SUMMARY OF THE INVENTION

According to the present invention, a solid-state relay is created by a power-switching device embedded in a semiconductor wafer which includes an optically transparent, electrically insulating surface, an organic light-emitting diode (OLED) formed on that surface, and a light-absorbing device integrated with the power-switching device yet electrically isolated from the diode.

It is an aspect of the present invention to fabricate efficient OLEDs using methods compatible with silicon technology and mass production, and integrate the diodes with photodetector power-switching devices.

Another aspect of the invention is to achieve electrical isolation between the light sources and the light-activated devices by an optically transparent, yet electrically insulating surface layer of the semiconductor wafer.

Another aspect of the invention is to select the photo-detecting devices from a group consisting of photodiodes coupled to amplifiers, phototransistors, and photodarlingtons.

Another aspect of the invention is to fabricate the solid-state relay in wafer form and separate the wafer after completion of the fabrication process into discrete units; the units may be individual chips or solid-state relay arrays.

Another aspect of the invention is to assemble an array of photovoltaic devices and MOSFETs on one side of a transparent and insulating substrate, and fabricate a matching array of OLEDs on the other side of the substrate, forming a multiple-relay module.

In the first embodiment of the invention, the transparent and insulating surface of the wafer is an overcoat layer made of a material selected from a group consisting of silicon nitride, silicon dioxide, and silicon oxynitride.

In the second embodiment of the invention, the transparent and insulating surface of the wafer is a sheet-like glass.

In the third embodiment of the invention, a sheet-like glass has an array of amorphous silicon solar cells and an array of MOSFETs on one side, and a matching array of OLEDs on the opposite side.

Several variations of structures and process steps are described. Electrical and optical parameters are discussed. By way of example, an optocoupler based on an OLED and p-i-n diode/amplifier integrated circuit is described in detail.

The technical advances represented by the invention, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 is a schematic and simplified cross section of a solid-state relay including an OLED and a photodetector integrated with a MOSFET, according to the invention.

FIG. 2 is a schematic and simplified electrical diagram of a sold-state relay including an OLED and a photovoltaic cell connected to a MOSFET.

FIG. 3 displays characteristics of a solid-state relay in the arrangement of FIG. 2. MOSFET turn-on time is measured as a function of OLED input current, with OLED internal quantum efficiency as parameter.

FIGS. 4A to 4C are schematic and simplified top views of the first and second surfaces of a substrate having the component parts forming multiple solid-state relays according to the invention.

FIG. 4A shows an array of photovoltaic cells assembled on the first surface of the substrate.

FIG. 4B shows an additional array of MOSFETs assembled on the first surface of the substrate and electrically connected to the respective photovoltaic cells.

FIG. 4C shows a matching array of OLEDs on the second surface of the substrate.

### DETAILED DESCRIPTION OF THE PREFERRED EMBODIMENTS

A solid-state relay (SSR) is a relay that uses only solid-state components, with no moving parts. A variety of solid-state power switching devices are used in electric circuits. A power switching circuit typically consists of a control circuit and a switching circuit. Electrical isolation is often desired between the control and the switching circuits in order to minimize the noise induced in the control circuit by the high-power switching in the switching circuit, or to minimize the damage to the control circuit due to a failure in the high-voltage switching circuit. Control and switching circuits also often do not share a common electrical ground, requiring electrical isolation between them.

Electrically-isolated power-switching can be achieved by using a light-activated switching device controlled by an electrically isolated light source. For example, light-activated thyristors, phototransistors, or photoconductors may be used with electrically isolated light-emitting diodes, which are driven by the control circuit. To reduce the power loss in the switching device, a metal-oxide-silicon field effect transistor (MOSFET) may be used as a switching device, which has very low resistance when it is turned on. To control the conduction state, a photovoltaic device coupled with an electrically-isolated light-emitting diode is employed to provide the required gate-source voltage for the MOSFET.

Conventional approaches at producing electrically isolated power switching devices have major obstacles: Fabricating inorganic semiconductor light-emitting diodes on silicon wafers of power switching devices is not practical (mismatch between III-V and silicon lattice constants, high fabrication temperature, low optical efficiency, etc.). Assembling a discrete light-emitting diode and a discrete light-activated switching device at the packaging level is expensive. The present invention removes these obstacles by the method of fabricating SSRs at the wafer-level, having integrated yet electrically isolated OLEDs.

In FIG. 1, the SSR according to the first embodiment of the invention, generally designated 100, is constructed on a semiconductor substrate 101. The semiconductor material can be silicon, silicon germanium, gallium arsenide or any other semiconducting material used in photolithographic manufacturing. Integral to substrate 101 is an integrated circuit (not shown in FIG. 1) and a semiconductor device 102 sensitive to electromagnetic radiation in a certain wavelength range. The radiation-sensitive device 102 is frequently referred to as photodetector. Radiation-sensitive device 102 is integral with switching circuit 103. Switching circuit 103 may be a high-power switching device or a MOSFET.

Laying over photodetector 102 is a flat portion of an optically transparent, electrically insulating layer 104, which has first surface 104a and second surface 104b. The radiation-sensitive device 102 is integral with second surface 104b. The organic diode 105, operable to emit electromagnetic radiation, is integral with the first surface 104a. The radiation-emitting diode is commonly referred to as OLED (organic light-emitting diode). Consequently, photodetector 102 is electrically isolated from OLED 105 and positioned in the path of the emitted radiation.

In the first embodiment of the present invention, layer 104 consists of one or more overcoat layers made of silicon nitride, silicon dioxide, or silicon oxynitride. Silicon nitride is a material widely used in silicon technology for its moisture-impenetrable characteristic; in this invention the layer is typically 0.8 to 1.2 μm thick. As mentioned above, the isolating characteristic of layer 104 is needed, for example, when the control circuit of the OLED 105 on one side operates in an electrically very noisy environment, possibly involving high voltage, related to the high power switching on the switching circuit side. Electrical isolation then provides safety for the delicate circuit side from strong electrical noise or high voltage.

In the second embodiment of the present invention, transparent and insulating layer 104 consists of sheet-like glass, which has a flat and smooth portion at least in the region of devices 102 and 105. Alternatively, layer 104 may be made of a glass-like inorganic material or polymeric material transparent for the electromagnetic radiation of OLED 105. In the case of glass (SiO2), the dielectric strength is approximately 10E7 V/cm. Consequently, a 1.0 μm thick SiO2 layer is enough to give 1000 V isolation and protection.

The organic radiation-emitting diode 105 consists of a stack of layers, deposited and structured in sequence, preferably at temperatures<100° C. The first layer is anode layer 106, preferably made of transparent ITO (Indium-tin oxide) in the thickness range from about 100 to 150 nm. Alternatively, a very thin (approximately 5 nm) semitransparent gold film may be used.

Anode layer 106 is followed by one or more organic layers 107. In FIG. 1, these layers provide a layer 107a for hole transport, made of TPD in the thickness range from about 15 to 30 nm. For some material combinations, layer 107a may be between 40 and 50 nm thick. Alternatively, hole transport layer 107a is made of PPV (polyparaphenylene-vinylene), between about 20 and 30 nm thick.

Organic layer 107a is followed by organic layer 107b, which provides the light emission and the electron transport. Layer 107b is preferably made of undoped Alq3 in the thickness range from about 55 to 80 nm. For some optical applications, emissive Alq3 layer 106b may comprise dopants for achieving the desired light intensity at the preferred wavelength (i.e., for changing the color of the emitted radiation). The dopant may be a dye such as QAC (quinacridone) or DCM (4-(dicyanomethylene)-2-methyl-6-(4-dimethylaminostyryl)-4H-pyran). The dye dopant may be evaporated concurrently with the Alq3 to further increase efficiency; doping concentrations usually <5%. The QAC-doped emissive layer 107b provides green light, the DCM-doped layer yellow light.

Alternatively, emissive layer 106b is made of CN-PPV (cyano-substituted PPV), between about 70 and 80 nm thick.

Organic layers 107 are followed by cathode layer 108, preferably made of aluminum or magnesium-aluminum, about 150 to 250 nm thick. Alternative materials for cathode layer 108 are silver or aluminum-calcium mixtures. Layer 108 is electrically connected to receive input signals. Overall, OLED 105 may have an area of about 5 mm².

The processes used in the fabrication method for OLED 105 are described in more detail in the abovementioned U.S. patent application TI-26315, to which the present invention is related. Overall, these processes are adaptable to miniaturization, compatible with silicon technology, and suitable for mass production.

Since the fabrication method described above lends itself to fabricating whole semiconductor wafers containing a plurality of units, the individual units have to be singulated from the wafer (typically by sawing or dicing) and packaged in order to form completed solid-state relays. An array of MOSFET-drivers can also easily be achieved by sawing the completed wafer into arrays.

According to the present invention, the OLED 105 is designed and fabricated such that the OLED active area is aligned with the window of the radiation sensitive device 102; device 102 is thus in the path of the radiation from OLED 105.

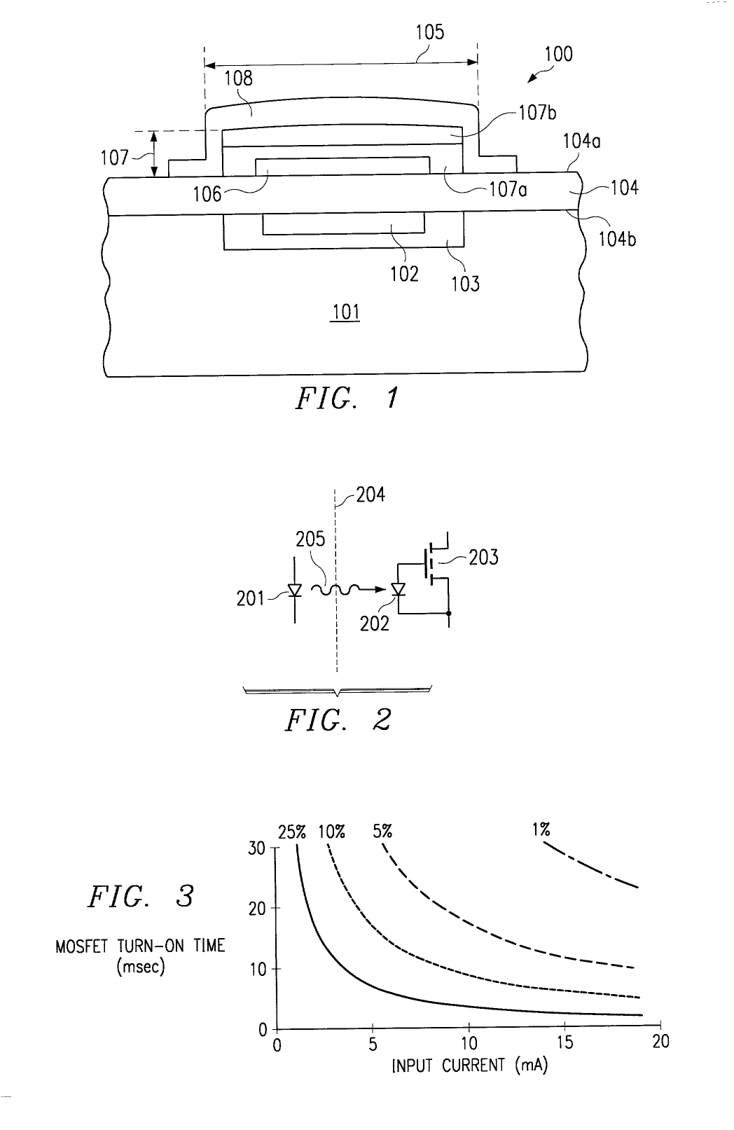

It is an important aspect of the present invention that radiation-sensitive device 102, integrated with the power-switching device 103, can be selected from a group consisting of a number of semiconductor devices, including a thyristor, a phototransistor, a photoconductor, or a metal-oxide-silicon field-effect transistor (MOSFET). In the schematic and simplified electrical diagram, FIG. 2 illustrates an solid-state relay using OLED 201 aligned to photovoltaic cell 202, which is connected to MOSFET 203, and an optically transparent, electrically insulating layer 204; the radiation 205 emitted by the OLED provides optical coupling to the photovoltaic cell as the radiation-detecting device.

By way of example, FIG. 3 displays some parameters and characteristics of a solid-state relay based on an OLED and a photovoltaic cell with MOSFET power switch (arrangement of FIG. 2), both fabricated by Texas Instruments Incorporated, Dallas, Tex., U.S.A. The solid-state relay is a floating, DC current switch based on a normally-off, n-channel MOSFET. The photovoltaic cell, connected between the gate and source of the MOSFET, is coupled with an electrically isolated OLED to control the conduction state of the MOSFET. By applying a high gate-source voltage (approximately 10 V), an on-state resistance lower than 0.05 Ω can be achieved, which is similar to the contact resistance of a mechanical relay of similar current rating. No external bias is available in the output side for amplifying the detected light signal. Consequently, a relatively large OLED input power is required for the solid-state relay. A typical charge at the gate, required to turn the MOSFET fully on (requiring gate-source-voltage about 10 V), is approximately 45 nC. If it is desired to turn the MOSFET on within 15 ms, the required cell current is 3 uA. If one adds a resistor (typically 1 to 2 MΩ) between gate and source of the MOSFET to reduce the time required to turn the MOSFET off, a current higher than 3 μA will be needed due to the charge loss through the resistor.

Since the OLED can be fabricated directly on the window of the photovoltaic cell, a fairly high photon coupling efficiency (in the order of 20%) between the OLED and the photovoltaic cell can be obtained. Based on a 20% light coupling efficiency, FIG. 3 plots the calculated characteristics of an OLED/MOSFET-based solid-state relay. The MOSFET turn-on time (measured in ms) is shown as a function of the OLED input current (measured in mA). The OLED internal quantum efficiency is used as parameter. It should be noted that internal quantum efficiencies higher than 10% have been demonstrated using the process for OLED fabrication described above. Since OLEDs typically generate green or orange light, photovoltaic cells based on amorphous silicon would work better than crystalline or polycrystalline silicon cells. The responsivities at 530 nm can be made similar by properly designing the cells, but the open-circuit voltage is about a factor of two higher in the amorphous silicon cells compared to the crystalline cells due to the larger bandgap of amorphous silicon. The size of the solid-state relay will be determined by the current density at which the OLED can operate reliably.

It should be noted that using a semitransparent thin gold film as the OLED anode instead of the transparent ITO (see the alternative process mentioned above) would reduce the coupling efficiency by at least about 50%.

In the second embodiment of the present invention, the transparent and insulating layer 104 of FIG. 1 consists of sheet-like glass. A preferred deposition method is the spin-on process.

In the third embodiment of the invention, multiple relay modules are fabricated using sheet-like substrates made of optically transparent and electrically insulating materials. Preferred material choices include glass, glass-like inorganic materials, and polymeric materials, which are transparent in the range of the desired electromagnetic radiation. On one surface of the sheet-like substrate, arrays of photovoltaic cells are attached, each cell connected to a power-switching device such as a MOSFET; on the opposite surface of the substrate, a matching array of OLEDs is fabricated.

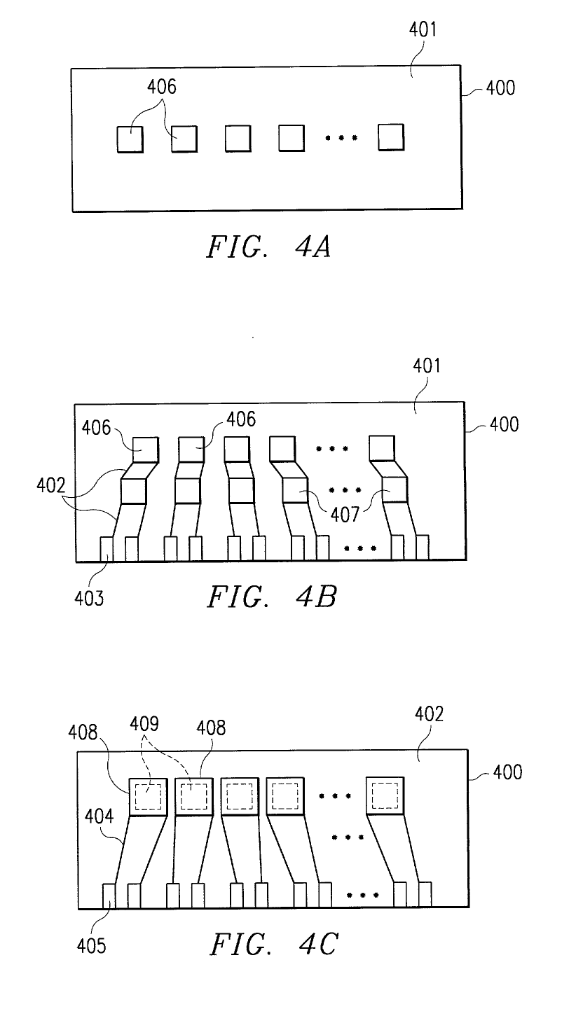

Key process steps of forming solid-state relay modules are schematically illustrated in FIGS. 4A to 4C. FIGS. 4A and 4B are simplified top view “snap shots” of the first surface 401 of substrate 400 at various process stages, FIG. 4C is a simplified top view “snap shot” of the second surface 402 of substrate 400. The process flow for fabricating the solid-state relay array comprises the steps of:

Depositing a metal layer on the first surface 401 and forming therein a pattern of electrical interconnections 402 between predetermined device attachment sites. By the same process step, edge connector contact areas 403 are formed.

Depositing a metal layer on the second surface 402 and forming therein a matching pattern of electrical interconnections 404 between predetermined device attachment sites. By the same process step, edge connector contact areas 405 are formed.

Attaching an array of radiation-sensitive devices 406 onto the predetermined sites on the first surface. For example, photovoltaic cells made of amorphous silicon are preferred devices.

Alternatively, an array of photovoltaic cells employing amorphous silicon may be fabricated directly on the substrate.

Attaching an array of power-switching devices 407 onto the predetermined sites on the first surface. For example, MOSFETs are preferred devices.

Forming an array of organic radiation-emitting diodes 408 onto the second surface 402. Each of these diodes is aligned with one of the radiation-sensitive devices 406, respectively, as indicated by the dashed lines 409 in FIG. 4C. The emitted radiation (usually light of a certain wavelength range) is directed toward the radiation-sensitive devices 406.

The array of OLEDs 408 is fabricated by the photolithographic method described above in more detail; it is compatible with silicon technology and includes the process steps of:

Depositing and forming an array of first electrodes on insulating substrate; the electrodes are electrically conductive and optically transparent.

Depositing and forming at least one organic layer on each of the electrodes, capable of transporting electrons and holes and emitting electromagnetic radiation.

Depositing and forming an array of second electrodes on the organic layers, respectively, each of these second electrodes configured to protect the organic layers, respectively.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. As an example, the OLEDs described may be modified for producing organic laser diodes by adding reflective surfaces surrounding a portion of the OLED, configured to provide a high-gain laser cavity. As another example, the fabrication processes described may be applied to OLEDs having an anode including a tunneling barrier at the interface with the hole transport layer for enhancing charge injection, and having a cathode including a tunneling barrier at the interface with the electron transport layer for enhancing charge injection. It is therefore intended that the appended claims encompass any such modifications or embodiments.

We claim:

1. An solid-state relay structure comprising:
a semiconductor chip having a power-switching device and an optically transparent, electrically insulating layer having first and second surfaces;
an organic diode integral with said first surface, said diode operable to emit electromagnetic radiation; and
said power-switching device including a radiation-sensitive semiconductor device integral with said second surface, electrically isolated from said diode, and positioned in the path of said radiation.

2. The solid-state relay according to claim 1 wherein said semiconductor chip is made of silicon, silicon germanium, gallium arsenide, or any other semiconductor material used in photolithographic manufacturing.

3. The solid-state relay according to claim 1 wherein said power-switching device is a thyristor, a metal-oxide-silicon field-effect transistor, a phototransistor, or a photoconductor.

4. The solid-state relay according to claim 1 wherein said radiation-sensitive semiconductor device is a photodiode or a photodiode integrated with an amplifier.

5. The solid-state relay according to claim 1 wherein said radiation-sensitive semiconductor device is a phototransistor.

6. The solid-state relay according to claim 1 wherein said radiation-sensitive semiconductor device is a photodarlington.

7. The solid-state relay according to claim 1 wherein said transparent and insulting layer is one or more overcoat layers made of a material selected from a group consisting of silicon nitride, silicon dioxide and silicon oxynitride.

8. The solid-state relay according to claim 1 wherein said transparent and insulating layer is a sheet-like glass.

9. The solid-state relay according to claim 1 wherein said organic diode is an organic light-emitting diode or an organic laser diode.

10. A method for fabricating solid-state relay structures on a semiconductor wafer, comprising the steps of:
forming a plurality of power-switching devices into said wafer, each of said power-switching devices operable to absorb electromagnetic radiation;
depositing an optically transparent, electrically insulating layer onto said wafer; and
forming a plurality of organic diodes onto said layer, each of said diodes aligned with one of said power-switching devices, respectively, and operable to emit electromagnetic radiation toward said radiation-absorbing device.

11. The method according to claim 10 wherein said forming of said diode comprises the steps of:
depositing and forming a first electrode on said insulating layer, said electrode being electrically conductive and optically transparent;
depositing and forming at least one organic layer on said electrode, capable of transporting electrons and holes and emitting electromagnetic radiation; and
depositing and forming a second electrode on said organic layer, configured to protect said organic layer.

12. The method according to claim 10 further comprising the steps of:
separating the resulting composite wafer into discrete units; and
assembling each of said units into a package, thereby completing the solid-state relay fabrication.

13. The method according to claim 12 wherein said discrete unit is a chip.

14. The method according to claim 12 wherein said discrete unit is an array.

15. A method for fabricating an array of solid-state relays on an optically transparent and electrically insulating sheet-like substrate, having first and second surfaces, comprising the steps of:
depositing a metal layer on said first surface and forming therein a pattern of electrical interconnections between predetermined device attachment sites;
depositing a metal layer on said second surface and forming therein a matching pattern of electrical interconnections between predetermined device attachment sites;
forming an array of radiation-sensitive devices onto said predetermined sites on said first surface;
attaching an array of power-switching devices onto said predetermined sites on said first surface; and
forming an array of organic diodes onto said second surface, each of said diodes aligned with one of said radiation-sensitive devices, respectively, and operable to emit electromagnetic radiation directed toward said radiation-sensitive device.

16. The method according to claim 15 wherein said forming of an array of diodes comprises the steps of:
depositing and forming an array of first electrodes on said insulating substrate, said electrodes being electrically conductive and optically transparent;
depositing and forming at least one organic layer on each of said electrodes, capable of transporting electrons and holes and emitting electromagnetic radiation; and
depositing and forming an array of second electrodes on said organic layers, respectively, each of said second electrodes configured to protect said organic layer, respectively.

17. The method according to claim 15 wherein said transparent and insulating sheet-like substrate is selected from a group consisting of glass, glass-like inorganic materials, and polymeric materials transparent for said electromagnetic radiation.

18. The method according to claim 15 wherein said forming an array of radiation-sensitive devices employs amorphous silicon material.

19. The method according to claim 15 wherein said step of forming an array of radiation-sensitive devices is replaced by the step of attaching an array of radiation-sensitive devices.
